(19) United States
(12) Patent Application Publication
(10) Pub. No.: US 2005/0245025 A1
(43) Pub. Date: Nov. 3, 2005

(54) Method of fabricating bottle trench capacitors using an electrochemical etch with electrochemical etch stop

(76) Inventor: Stephan P. Kudelka, Ottendorf-Okrilla (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/150,142

(22) Filed: Jun. 13, 2005

Related U.S. Application Data
(62) Division of application No. 10/775,163, filed on Feb. 11, 2004.

(51) Int. Cl. H01L 21/8242

(52) U.S. Cl. 438/243; 438/386

(57) ABSTRACT

A method of forming trench capacitors in, e. g., a DRAM device, using an electrochemical etch with built-in etch stop to fabricate well-defined bottle-shaped capacitors is described. The process includes formation of a sacrificial silicon layer after initial deep trench formation, wherein the sacrificial layer is formed by doping, and upon its removal, a bottle trench is formed. A second region of doped silicon located below the sacrificial layer is resistant to the chemical etch performed to remove the sacrificial layer, and thereby renders the bottle trench formation process self-limiting.

### BACKGROUND OF THE INVENTION

1. Field of the Invention

The present invention relates generally to semiconductor devices. More particularly, the present invention relates to methods of making and the structure of trench capacitors in memory devices.

2. Background Information

The semiconductor industry requires miniaturization of individual devices such as transistors and capacitors to accommodate the increasing density of circuits necessary for semiconductor products. One common semiconductor product is a dynamic random access memory (“DRAM”), which may incorporate billions of individual DRAM memory units (cells), each capable of storing one data bit. A DRAM cell includes a planar access transistor and a storage capacitor. The access transistor transfers charge to and from the storage capacitor to read or write data. The total amount of charge stored in the capacitor must exceed a threshold value, which is based on the minimum amount of charge required to read the capacitor by a sensing device, and the frequency at which the capacitors are re-charged (refreshed). Because the capacitors do not retain their charge for an infinite time, periodic capacitor refreshing is required to replace leaking charge before the total charge retained falls below the value needed to read a memory cell.

In order to increase the memory capacity on a chip, i.e., the number of cells, there is a need to shrink the amount of horizontal area on the chip used by each cell, which requires a reduction in transistor and/or capacitor size. However, as the total cell size is reduced, the amount of charge retained in a horizontal planar capacitor may not be sufficient to ensure proper device operation, since the capacitance is directly proportional to the planar area of the device. One technique to address this problem is to fabricate trench capacitors, which have a trench shape when viewed in cross section and are formed by vertical etching into the silicon substrate, typically using gaseous species. FIG. 1a shows an the ideal trench capacitor 1, where insulator 8 has a U-shape and is bounded on the outside by an outer capacitor electrode (plate) 2, and on the inside by an inner plate 7. Plate 2 represents the ‘bottom’ plate formed by doping the silicon substrate and contains surfaces 3, 3′, and 4, with dimensions, d1, d2, and w1, respectively. In a cylindrical trench, surfaces 3 and 3′ are part of the same cylinder wall. Similarly, the “top” plate 7 has vertical surfaces 6, 6′, and horizontal surface 5, which are approximately the same dimensions as bottom plate surfaces, 3, 3′, and 4, respectively.

In terms of behavior and size, it is well known to those skilled in the art that the ideal trench capacitor of FIG. 1a can be approximated by an equivalent planar capacitor shown in FIG. 1b, containing plates 11, 13 and insulator 12, whose width W equals the sum of d1, d2, and w1. In current technology, a trench typically has a depth in the range of 4-8 μm and an oval or rounded top-down-view shape, with a horizontal dimension which may be less than 0.5 μm. Referring to FIGS. 1a and 1b, and assuming the same insulator thickness, a trench capacitor of 0.5 um width (w1) and 4 um depth (d1) has the approximate capacitance of a planar capacitor of 8.5 um width. That is, the trench capacitor is equivalent to a planar capacitor whose width W is the sum of the trench capacitor width and two times its depth. Thus, the trench capacitor structure permits a large capacitance per planar unit area of substrate, while at the same time allowing the device cell to occupy a small portion of the cell area.

For a given DRAM cell size, where the size of the horizontal trench opening is fixed, the capacitance in a trench capacitor can be increased simply by increasing the trench depth. However, it is also well known to those skilled in the art that the vertical etch that is used to form the trench typically results in a tapered trench profile, which produces a smaller surface area and therefore lower capacitance than if the trench formed an ideal cylindrical shape. FIG. 2 shows “vertical” walls 21, 21′, and trench bottom 22. The walls taper in during etch, causing the bottom of the trench to taper toward a point. The tapering is due in part to the increased ratio of depth to width in the trenches as they are etched deeper, which reduces the ability of the gaseous etching species impinging from outside the trench to strike the outer portions of the trench bottom. Thus, for a given planar hole diameter, there is a limit to the trench depth that is attainable, since the trench walls taper in towards a point.

Related art teaches methods of forming better trench capacitor geometries, such as the “deep trench bottle etch (BE) process”. FIG. 3 illustrates the appearance of a trench formed using the BE process. The BE process includes formation of an insulating collar 25, inside the top of the silicon trench after initial deep trench etch which is used to form surfaces 3, 3′, and 4, shown as a dashed line. This is followed by a liquid chemical etch, which removes the silicon residing underneath the collar in the lower part of the trench, and results in a bottle-shaped final profile of the trench. The etch tends to be isotropic; that is, the silicon at the surface of vertical and horizontal portions of the trench is etched at about the same rate. FIG. 3 shows that the final trench contains vertical surfaces 26, 26′, and horizontal surface 27, all larger than their original counterparts 3, 3′, and 4, respectively. In addition, new surfaces 28 and 28′ are formed at the top of the trench, adding to the overall surface area. In this manner, the area of the trench capacitor is made larger by increasing both the depth and the width of the trench.

It will be appreciated by those skilled in the art that care must be employed to form bottle-shaped trenches using a wet chemical etch in the manner described above. The uniformity of such etches depends on many variables, such as the concentration of active etching species in the liquid etchant, which can vary over time, causing the silicon removal in the lower trench to increase or decrease. Additionally, control of the effective time that the trench is exposed to liquid etchant may be difficult. The etch time employed to form the bottle trench is based on the known etch rate of silicon when subject to a given concentration of etchant. After the desired etch time, wafers containing the DRAM chips are rinsed and dried to dilute, and then remove, the etchant from the bottle trenches and prevent further etching of silicon. However, the extremely small size and bottle shape of the trenches can act to retard liquid etchant removal, resulting in an effective etch time greater than desired. In addition, the etch profile within a trench may not be uniform, due to incomplete or tardy removal of liquid etchant in certain regions such as comers in the trench. For the above reasons, among others, the uniformity of trench size may be difficult to control, and can lead to failures where adjacent bottle trenches merge, as depicted in FIG. 4. FIG. 4 illustrates an array of equally-spaced bottle trenches 31, 32, 33, and 34 after bottle etch and rinse. The profiles are sketched to illustrate less-than ideal final trench shapes that may form for the reasons mentioned above. While the internal surfaces 43 and 44 of trenches 33 and 34, respectively, remain distinct, surfaces 41 and 42 of trenches 31 and 32, respectively, have merged leading to a storage failure in the corresponding memory cells.

A further problem with the bottle etch process described in related art is that the nonunifomity can lead to significantly lower than ideal trench capacitance. In order to reduce the risk of merging of trenches that is inherent in the process, a maximum tolerable trench width can be established, based on the separation distance of adjacent trenches. Then, a nominal bottle etch process recipe is developed to allow for variations in the bottle etch process. FIGS. 5a-c illustrate examples of three different chemical etch conditions applied to form a bottle trench after an initial vertical etch. FIG. 5a shows a group of trenches after chemical etch for the nominal process conditions, which results in trench 51 of width d5. This is the result that obtains when the etch time, etchant concentration, and rinse are all carried out exactly according to the designed etch recipe. The trenches in FIG. 5b illustrate the result of trench formation using the minimal tolerable chemical etch condition, which may denote the state where the effective etch time deviates below the nominal time by the greatest allowable amount; and the actual etchant concentration is less than the nominal by the maximum tolerable amount. The resulting trench 52 has width d6, which is less than d5. The converse of FIG. 5b is shown in FIG. 5c, where the trenches have been etched to the maximum size, width d7, where the effective etch time and concentration exceed the nominal values by the maximum tolerable amount.

The value of d7 minus d6 (V) represents the variability in trench size resulting from the chemical etch process, which may be on the order of tenths of micrometers. The nominal trench size d5, must be smaller than d7 by a value that may be about V/2. Thus, the average capacitor will have a significantly smaller dimension (with concomitantly lower capacitance) than the maximum size capacitor.

A further result of a large variability in the chemical etch process is the production of many trenches with significantly lower capacitance (or size) than nominal, as illustrated by the capacitor structures shown in FIG. 5b.

In view of the foregoing, it can be appreciated that a substantial need exists for improvement of trench storage capacitors.

### SUMMARY OF THE INVENTION

The present invention relates to structures and processes that improve storage capacitors. In particular, a process is disclosed that overcomes present limitations on production of trench capacitors. An exemplary embodiment of the current invention comprises a bottle trench capacitor structure formed by selective removal of a uniform sacrificial silicon layer of pre-determined thickness from the lower part of the trench. An object of the present invention is to produce bottle trench capacitors in a manner such that the risk of merging adjacent trenches during processing is minimized. This is accomplished in an exemplary embodiment of the current invention by use of a selective chemical etch with a built-in electrochemical etch stop. A bilayer region of silicon in the trench structure is formed such that the surface layer is removed under electrochemical etch without removal of the bottom layer. In this manner the amount of silicon removed from the trenches can be limited, and the problem of merging of adjacent trenches is avoided.

A further aspect of the present invention relates to the production of trenches of uniform size, such that the capacitance variation between trench devices is minimized. It is well known to those skilled in the art that, in addition to variation in dielectric layer thickness, the primary influence on trench capacitance is the internal trench surface area, which is, in turn, directly proportional to the trench size. In exemplary embodiments of the current invention, the final trench size is in large part determined by removal of a sacrificial silicon layer of well-controlled thickness as detailed below. This results in capacitors of more uniform dimension compared to those produced by conventional processes. An additional object of the current invention is the fabrication of trenches with maximum capacitance attainable for a given DRAM cell size and trench separation. It will be appreciated by those skilled in the art that the more uniform process contained in embodiments of the present invention makes it possible to increase the average trench width without increased risk of failure due to merging of trenches.

### BRIEF DESCRIPTION OF THE DRAWINGS

FIGS. 1a and 1b represent, respectively, an ideal trench capacitor in cross-section, and its planar capacitor equivalent.

FIG. 2 is a cross section representing realistic trench profiles achieved using standard vertical etch processes.

FIG. 3 is a drawing illustrating a bottle trench formed by a wet chemical etch employed after a standard vertical etch step according to known art.

FIG. 4 is a drawing illustrating bottle trench non-uniformities and failure due to wet chemical etch process variation.

FIGS. 5a-c are schematic drawings illustrating the impact of wet chemical etch process non-uniformity on average dimension of bottle trenches.

FIGS. 6a-d are drawings illustrating bottle trench formation according to an embodiment of the present invention.

FIG. 7 illustrates details of electrochemical etch processing steps according to an embodiment of the present invention.

FIG. 8 is a drawing illustrating an electrochemical etch apparatus according to another embodiment of the current invention.

FIG. 9 illustrates a current-voltage passivation curve for n-type silicon.

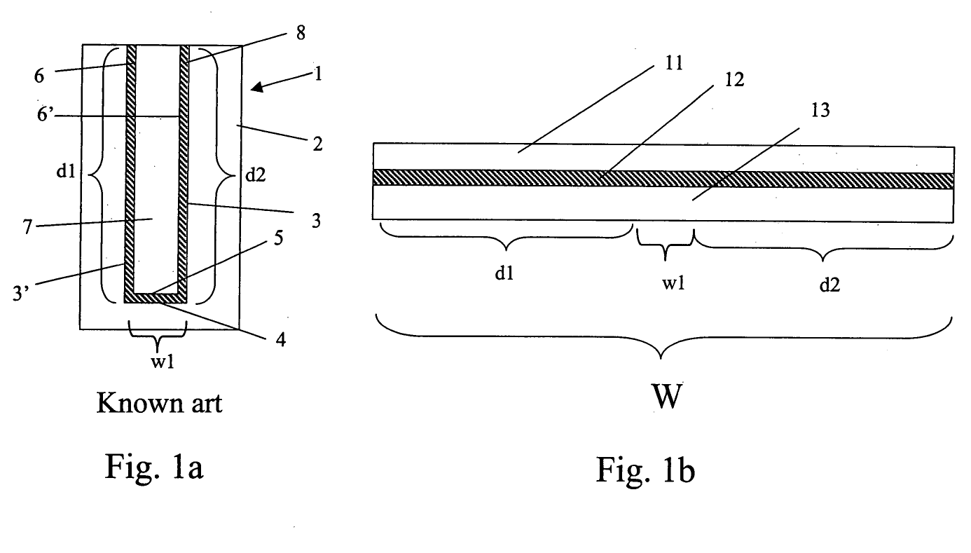

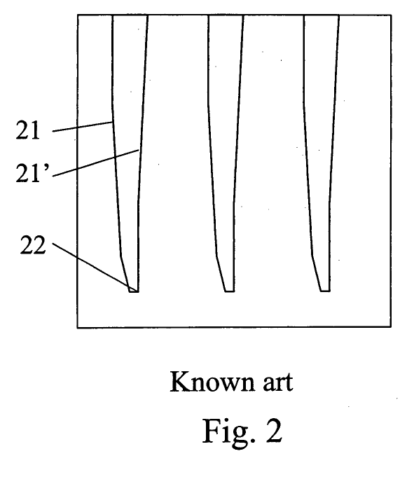

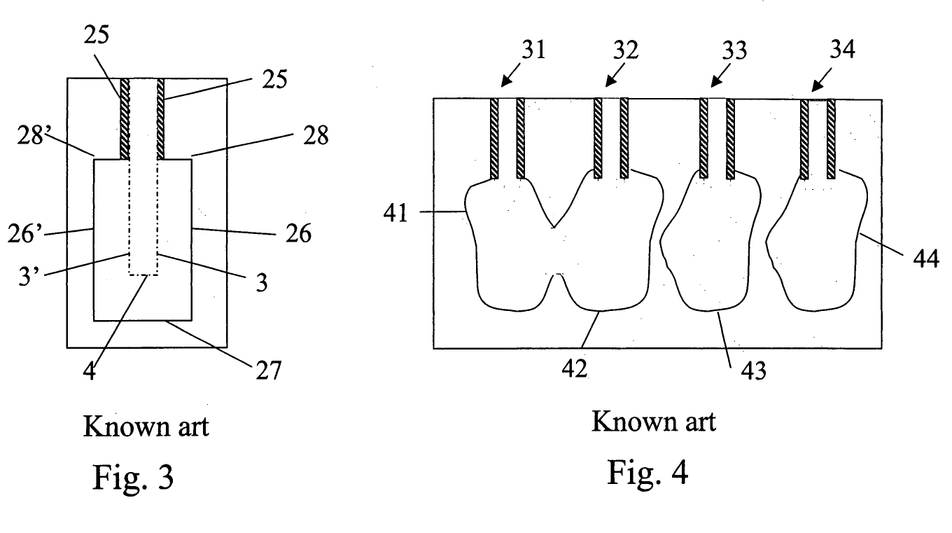

### DETAILED DESCRIPTION OF THE INVENTION

Preferred embodiments of the present invention are described below, with reference made to the enclosed drawings. Before one or more embodiments of the invention are described in detail, one skilled in the art will appreciate that the invention is not limited in its application to the details of trench structure and the arrangement of steps set forth in the following detailed description or illustrated in the drawings. The invention is capable of other embodiments and of being practiced or being carried out in various ways. Also, it is to be understood that the phraseology and terminology used herein is for the purpose of description and should not be regarded as limiting.

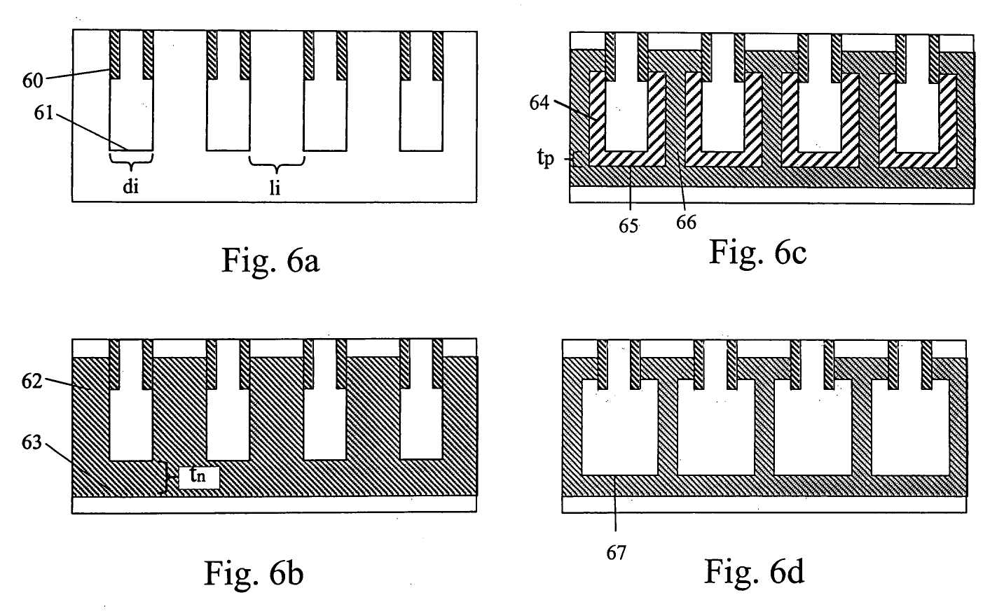

The present invention is related to methods and structures for providing large and uniform DRAM trench capacitors. Current methods of bottle trench capacitor fabrication employ non-selective wet etching of silicon to enlarge the trench below a collar region. This process entails the risk of complete silicon removal between trenches (“trench merge”, as shown in FIG. 4) if the etch process is not terminated in a timely fashion. According to an embodiment of the present invention, a selective etch process is employed to form the bottle trench that substantially eliminates the etch variability seen in the related art. Exemplary embodiments are now described in relation to FIGS. 6-10.

In FIG. 6a, after standard deep trench formation using well known techniques, an insulating collar 60 is fabricated so that it lines the top part of the trench. In an exemplary embodiment, the collar is formed by depositing a photoresist material to line the bottom of the trench, followed by growth of an oxide on the inside surface near the top of the trench. In some embodiments this collar may comprise a nitride, or related material that is resistant to a subsequent bottle etch. After oxide collar formation, the resist in the lower region of the trench is chemically stripped while leaving the oxide collar untouched. In the lower part of the trench the silicon is thus unprotected, forming surface 61. The adjacent vertical walls of neighboring trenches are separated by distance lᵢ. After insulating collar formation, an n-type dopant is introduced into the silicon in the lower trench, forming region 62, as illustrated in FIG. 6b. In an exemplary embodiment, this is accomplished by gas-phase doping methods well-known to those skilled in the art. The depth of the n-type doping, tₙ, is defined (with reference to FIG. 6b) by the vertical distance between the bottom of the trench and the bottom of the n-doped silicon layer, border 63. This depth extends equally from all trench surfaces, and is preferably large enough so that the n-doped silicon region extends entirely between adjacent trenches, as depicted in FIG. 6b. In a preferred embodiment, the doping level is about 1-5E18 cm⁻³. Subsequently, as illustrated in FIG. 6c, a p-type dopant is introduced to the trench region, extending to a depth tₚ, less than that of the n-type region. The concentration of p-type dopant exceeds that of the n-type dopant previously introduced, resulting in a distinct p-type silicon layer 64 extending from the trench surface to a boundary 65 with the n-type layer, as shown in FIG. 6c. After p-type layer formation, the dual-doped trench structure contains regions 62 and 64 which are comprised of activated dopants creating a p-n junction at interface 65. Although not essential to the current invention, it will be appreciated by skilled artisans that the horizontal width of the p-type layer may be substantially equivalent to the vertical depth, tₚ, as defined above. FIG. 6c further shows that, in an exemplary embodiment, a region of n-type silicon 66 remains between the vertical portion of p-type layers in adjacent trenches. Thus, in an exemplary embodiment of the current invention, tₚ is typically less than half of Lᵢ, the spacing between the vertical edges of neighboring trenches. In a preferred embodiment, the level of p-type doping is in the range of 1E19 cm⁻³ or higher, rendering the layer a “p+” silicon region. It is also to be appreciated that the gas phase doping process allows the growth of layers of highly uniform thickness when compared to the trench dimensions. That is, while overall trench width may be in the range of 100-1000 nm, the expected variation in tₚ may be only several nm.

Subsequently, the trenches are subjected to an electrochemical etch under applied bias voltage, wherein, in a preferred embodiment, the etch solution comprises aqueous solutions comprising water (H₂O) and hydroxide (NH₄OH or KOH). This results in the complete removal of layer 64 while leaving the region 62 substantially intact, forming an exposed n-type silicon surface 67, as illustrated in FIG. 6d. The three dimensional shape of the bottle trench shown in FIG. 6d is in part determined by the shape of the neck region, which is, in turn, determined by the shape of mask used to form the initial vertical trench. Embodiments of the present invention include trenches formed from bottle shaped structures whose neck region in top-down view appears alternatively as an oval, a circle, a square, or a rectangle.

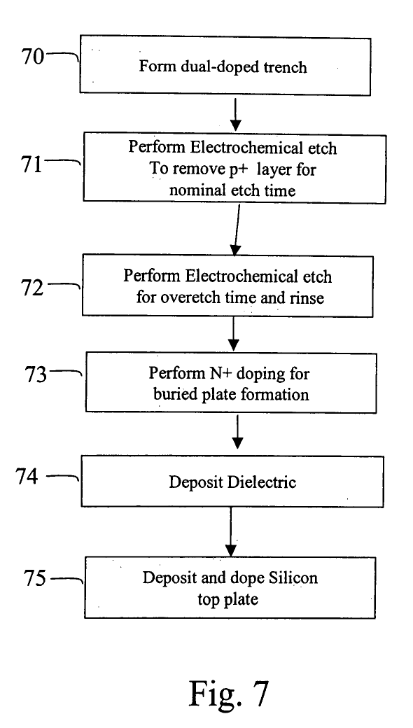

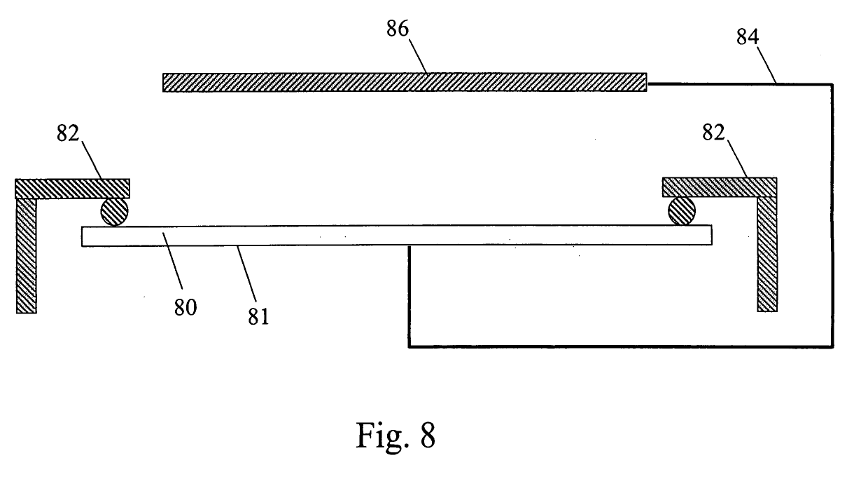

FIG. 7 illustrates an exemplary process flow of an embodiment of the current invention. After processing to form the dual-doped trench structures as depicted in FIG. 6c, shown as step 70 in FIG. 7, the silicon wafers containing the trench devices are placed in an electrochemical etching apparatus containing an hydroxide/water etch solution, step 71. In a preferred embodiment, they are placed in a holder within the apparatus, which provides electrical contact to the backside of the silicon wafer, as depicted in FIG. 8. A wafer 80 is held by clamps 82, while an electrical contact is made to the backside wafer surface 81. An electrical conductor 84 connects to a counter electrode 86. A bias of approximately +1.2 V is subsequently applied between the wafer backside 81 and the counter electrode 86 in the etching apparatus. Etch step 71 is performed until the p+ silicon layer in the trench is completely removed. The wafer remains in the apparatus and subject to continued applied bias for a subsequent “overetch,” step 72. The overetch step is performed to assure that the p+ layer is removed in all trenches so the overetch time employed preferably accounts for variations in process temperature, etch concentration, and related factors. In a preferred embodiment, the ratio of etch rates of p-type:n-type silicon (p:n etch selectivity) can be as high as 200:1, depending on the exact concentration of hydroxide and the solution temperature. For purposes of example, given nominal etch conditions having a p:n etch selectivity of 100:1 and a p-type removal rate of a 50 nm layer in 100 seconds, step 71 may be performed for 100 seconds to remove a 50 nm p+ region. Then overetch step 72 to remove any remnant p+ may be performed for an additional 50 second etch time, without substantial risk of etching significantly into the n-silicon region. Under nominal conditions where the 50 nm p-type layer is actually removed in exactly 100 seconds, the 50 seconds overetch of step 72 would remove only 0.25 nm of the n-type silicon region, about one layer of silicon atoms.

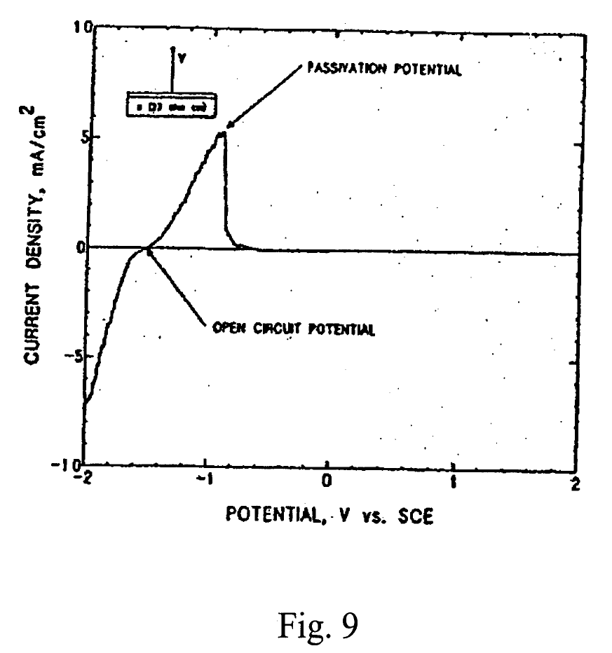

FIG. 9 helps explain the mechanism contributing to the enhanced p:n etch selectivity employed in the current invention. The graph shows that above a certain potential Si passivates (>−0.8 V). This characteristic applies for both n-type and p-type silicon. However, since the trench structure contains a reverse biased n/p junction, no current flows through the junction. Thus, the potential drop occurs at the n/p junction and not at the surface of the p layer where it contacts the etch solution. Thus, this leaves the p surface unbiased at open circuit potential and the p-type silicon is subject to continual hydroxide etch. When the n-type silicon is exposed, the current rises and causes immediate passivation of the surface, blocking any further etching.

After electrochemical etch to remove the sacrificial p-type layer, conventional steps, well-known to skilled artisans, are employed, including silicon doping to form the buried plate of the capacitor, step 73 in FIG. 7, followed by capacitor dielectric deposition 74 and trench top electrode formation 75.

An advantage of the current invention is that because of the high selectivity of the electrochemical etch step, the n-type layer 62 shown in FIG. 6b acts as an etch stop, where the etch rate approaches zero once the n-silicon layer is contacted. Thus, the wet etch process no longer needs to be precisely controlled to determine the amount of silicon removed. Because the etch rate of n+ silicon is so low, one can vary etch concentration, time, and temperature within a wide range, without substantially altering the amount of silicon removed. Thus, in a preferred embodiment of the present invention, the amount of silicon removed during chemical etch is no longer determined by variations in the wet chemical etch process. Rather, the total silicon removed is simply determined by the depth of layer 64, tₚ, since the etch process essentially terminates when the n-type layer 62 is encountered. Thus, as long as tₚ is sufficiently small that etch stop layer 66 remains between adjacent trenches, the chance of trench merge can be virtually eliminated.

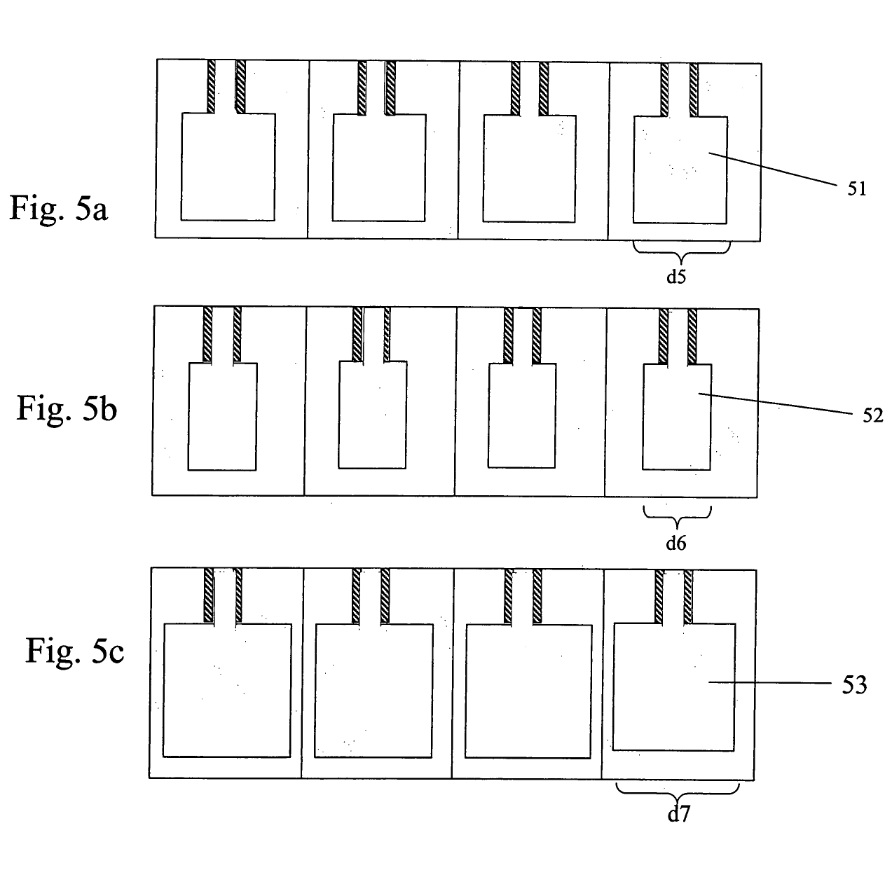

As previously noted, another advantage of the present invention is the ability to fabricate larger bottle trenches for a given DRAM cell size. Referring to FIGS. 5a-c, it is noted that in the present invention the variation in the amount of trench silicon removed, V, does not significantly depend on etch process variation, since the process is designed to remove all of the p+ layer without removing a significant amount of n-silicon. Thus, V arises only from variation in tₚ, which is on the order of a few nm. This affords the possibility of designing the nominal trench width to be much greater than in the conventional process, where no etch stop exists, resulting in a much larger V. A still further advantage of the current invention is that since V is so small, the variability in capacitance of trench capacitors among different DRAM cells is minimized.

An additional advantage of the current invention is that it is possible to scale the process so that it can be successfully employed in smaller DRAM cells in subsequent technologies. That is, as overall trench spacing decreases to accommodate greater device density and performance, the amount of silicon removed in the electrochemical etch process can be easily reduced. This is because the latter depends solely on the thickness of the sacrificial p-type layer, which is determined by precise doping methods.

Embodiments of structures and methods for fabrication of deep trench capacitors with enhanced uniformity and resistance to structural failure during processing have been described. In the foregoing description, for purposes of explanation, numerous specific details are set forth to provide a thorough understanding of the present invention. It will be appreciated, however, by one skilled in the art that the present invention may be practiced without these specific details. Furthermore, one skilled in the art can readily appreciate that the specific sequences in which methods are presented and performed are illustrative and it is contemplated that the sequences can be varied and still remain within the spirit and scope of the present invention.

In the foregoing detailed description, structures and methods in accordance with embodiments of the present invention have been described with reference to specific exemplary embodiments. Accordingly, the present specification and figures are to be regarded as illustrative rather than restrictive. The scope of the invention is to be defined by the claims appended hereto, and by their equivalents.

1. A method for fabricating a storage capacitor comprising:
forming an initial deep trench structure through an etching process;
forming a sacrificial doped silicon layer extending from a surface of the interior of said deep trench into the silicon substrate, wherein a boundary is established between said doped sacrificial silicon layer and said silicon substrate;
selectively removing said sacrificial doped silicon layer from said trench interior surface;
fabricating a buried plate electrode;
fabricating a capacitor dielectric; and
fabricating a top electrode.

2. The method of claim 1, wherein said sacrificial doped silicon layer comprises p-doped silicon.

3. The method of claim 2, wherein said selectively removing said sacrificial doped silicon layer further comprises chemical etching using an aqueous solution of hydroxide.

4. The method of claim 2, wherein said p-doped silicon layer is formed by gas phase doping.

5. The method of claim 2, wherein said selectively removing said sacrificial doped silicon layer further comprises:
forming an n-type region extending from said internal p-type silicon interface further into said silicon substrate; and
selectively etching said p-type layer such that said n-type region remains substantially unetched during said selectively etching said p-type layer.

6. The method of claim 5, wherein said selectively etching said p-type layer comprises:
exposing said p-type layer to an aqueous solution of hydroxide;
applying a positive bias of about 1.2V between a counter electrode and a backside of a wafer containing said p-type layer; and
maintaining the positive bias for a duration sufficient to entirely remover said p-type layer.

7. The method of claim 5, wherein said p-type layer is formed by gas-phase doping.

8. The method of claim 6, wherein said p-type layer is formed by gas-phase doping.

9. The method of claim 1, wherein formation of said initial deep trench structure additionally comprises forming an etch-resistant collar located on a surface of the trench interior in a top region of said trench.

10. An array of DRAM trench capacitors, wherein each trench capacitor has a bottle shaped trench cross-section of substantially uniform shape when viewed in cross-section, and wherein the uniformity of bottle trench dimensions does not vary substantially among capacitors within the array.

11. The array of claim 10, wherein the steps for forming the array include:
forming an initial deep trench structure in a silicon substrate through an etching process;
forming a sacrificial doped silicon layer extending from a surface of an interior of said deep trench into the silicon substrate, resulting in an internal p-type silicon/silicon interface;
selectively removing said sacrificial doped silicon layer from said trench interior surface; and
forming a buried plate electrode, capacitor dielectric, and top electrode.

12. The array of claim 11, wherein said sacrificial doped silicon layer comprises p-doped silicon.

13. The array of claim 12, wherein said p-doped silicon layer is formed by gas phase doping.

14. The array of claim 11, wherein said selectively removing said sacrificial doped silicon layer comprises:
forming an n-type region extending from said internal p-type silicon interface further into said silicon substrate; and
selectively etching said p-type layer such that said n-type region remains substantially unetched during said selectively etching said p-type layer.

15. The array of claim 14, wherein said selectively etching said p-type layer is performed by chemical etching using an aqueous solution of hydroxide of potassium or ammonia, further comprising the step of applying a bias voltage to said p-type layer during said chemical etching.

16. A method for fabricating bottle-shaped etched structures in silicon, comprising:
forming an initial narrow etched region by a directional silicon etching process;
forming an etch-resistant collar in the top portion of the etched region;
forming a sacrificial doped silicon layer extending from a surface of an interior of said etched region further into said silicon, wherein said sacrificial doped silicon layer is fabricated by gas phase doping of said silicon; and
selectively removing said sacrificial doped silicon layer by etching in a chemical solution.

17. The method of claim 16, wherein said selectively removing said sacrificial doped silicon layer further comprises:
forming an n-type region extending from said internal p-type silicon interface further into said silicon substrate; and
selectively etching said p-type layer such that said n-type region remains substantially unetched during said selectively etching said p-type layer.

18. The method of claim 17, wherein said selectively etching said p-type layer comprises:
exposing said p-type layer to an aqueous solution of hydroxide;
applying a positive bias of about 1.2V between a counter electrode and a backside of a wafer containing said p-type layer; and
maintaining the positive bias for a duration sufficient to entirely remover said p-type layer.
